(19) United States
(12) Patent Application Publication
(10) Pub. No.: US 2019/0318914 A1
(43) Pub. Date: Oct. 17, 2019

(54) PROCESSING APPARATUS AND METHOD FOR CONTROLLING PROCESSING APPARATUS

(71) Applicant: Tokyo Electron Limited, Tokyo (JP)

(72) Inventors: Naohiko OKUNISHI, Miyagi (JP); Hiroshi NAGAHATA, Miyagi (JP); Masaru ISAGO, Miyagi (JP); Hiraku MURAKAMI, Miyagi (JP)

(21) Appl. No.: 16/378,956

(22) Filed: Apr. 9, 2019

(30) Foreign Application Priority Data
Apr. 16, 2018 (JP) 2018-078665

(51) Int. Cl. H01J 37/32

(52) U.S. Cl. CPC H01J 37/32183; H01L 21/67069; H01J 37/32568

(57) ABSTRACT

A processing apparatus that processes an substrate inside a processing container includes a first electrode disposed inside the processing container, the first electrode being configured to mount the substrate, a second electrode disposed so as to face the first electrode, an electric power supply unit configured to apply high frequency power to the first electrode or the second electrode, a coil disposed on a surface opposite to the surface to which the first electrode or the second electrode faces and on a surface of any one of the first electrode and the second electrode, one end of the coil being connected to the any one of the the first electrode and the second electrode, another end of the coil being connected to ground, and an adjusting mechanism configured to control a magnetic field strength of a magnetic field that is from the coil and passes through the coil.

### CROSS-REFERENCE TO RELATED APPLICATIONS

This patent application is based upon and claims priority to Japanese Patent Application No. 2018-078665 filed on Apr. 16, 2018, the entire contents of which are incorporated herein by reference.

### BACKGROUND OF THE INVENTION

### 1. Field of the Invention

The present invention relates to a processing apparatus and a method for controlling the processing apparatus.

### 2. Description of the Related Art

For example, Patent Documents 1 and 2 propose that multiple electromagnets are arranged on an upper surface of an upper electrode of a plasma processing apparatus and electric currents are applied from an electric current source to coils of the multiple electromagnets so as to enhance controllability of distribution of the etching rate or an in-plane evenness of plasma density.
[Patent Document 1] Japanese Laid-open Patent Publication No. 2017-73518
[Patent Document 2] Japanese Laid-open Patent Publication No. 2014-158005

### SUMMARY OF THE INVENTION

According to an aspect of the embodiment, a processing apparatus that processes a substrate inside a processing container includes a first electrode disposed inside the processing container, the first electrode being configured to mount the substrate, a second electrode disposed so as to face the first electrode, an electric power supply unit configured to apply high frequency power to the first electrode or the second electrode, a coil disposed on a surface opposite to the surface to which the first electrode or the second electrode faces and on a surface of any one of the first electrode and the second electrode, one end of the coil being connected to the any one of the the first electrode and the second electrode, another end of the coil being connected to ground, and an adjusting mechanism configured to control a magnetic field strength of a magnetic field that is from the coil and passes through the coil.

### BRIEF DESCRIPTION OF THE DRAWINGS

FIG. 1 illustrates an example of a plasma processing apparatus according to an embodiment of the present invention.

FIG. 2 illustrates an example of an arrangement of multiple coils of the embodiment.

FIG. 3 illustrates an example of an adjusting mechanism of the embodiment.

FIG. 4 illustrates an example of an adjusting mechanism of the embodiment.

FIG. 5 illustrates an example of experimental results of electric field strength and etching rates with respect to switch-on and switch-off of the switch circuit of the embodiment.

FIG. 6 illustrates an example of an adjusting mechanism of a modified example 1.

FIGS. 7A and 7B illustrate an example of an adjusting mechanism of a modified example 2.

FIG. 8 illustrates an example of an adjusting mechanism of a modified example 3.

FIGS. 9A and 9B illustrate an example of an adjusting mechanism of a modified example 4.

FIGS. 10A and 10B illustrate examples of adjusting mechanisms of a modified example 5.

FIGS. 11A to 11C illustrate examples of arrangements of multiple coils of the embodiment.

### DETAILED DESCRIPTION OF EMBODIMENTS

The present disclosure provides a processing apparatus that can accurately control plasma density and a method for controlling the processing apparatus.

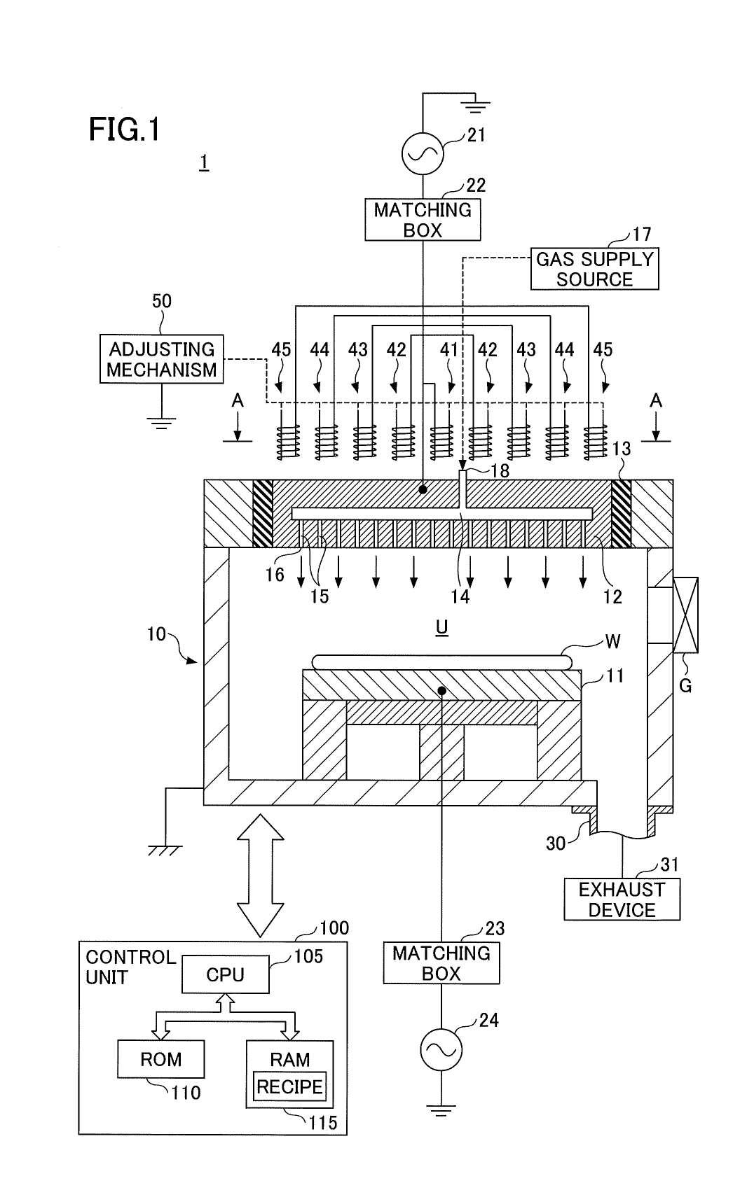

A description of embodiments of the present invention is given below, with reference to the FIG. 1 through FIG. 11C.

The embodiments described below are only examples and the present invention is not limited to the embodiments.

Through all figures illustrating the embodiments, the same references symbols are used for portions having the same function, and repetitive explanations of these portions are omitted.

Reference symbols typically designate as follows:
10: processing container;
11: mounting stage (lower electrode);
12: gas shower head (upper electrode);
17: gas supply source;
21: high frequency power source;
24: high frequency power source;
40, 41-45: coil;
46: yoke;
50: adjusting mechanism;
50a: switch circuit;
50b: impedance adjusting circuit;
50c: up down driving mechanism;
50d: rotary driving mechanism;
50e: expansion and contraction adjusting mechanism;
50f: yoke driving mechanism;
100: control unit; and
L: feed line.

### INTRODUCTION

Along with microminiaturization of a semiconductor, an influence of a variation in a process characteristic caused by a difference between processing apparatuses performing an etching process or the like or consumption of parts given to a result of processes such as the etching process becomes higher in recent years. As a countermeasure, the variation of the process characteristic is made small by controlling the temperature of the mounting stage of the wafer for many zones of the mounting stage. However, when only a temperature is controlled, the variation of tapered angle or the like of a shape may occur even if a control of matching an etching rate or a Critical Dimension (CD) is performed. Therefore, only the temperature control is insufficient to make the process characteristic even. Therefore, this embodiment describes a processing apparatus that can control an in-plane distribution of a plasma density with a simple structure at a low cost and a method for controlling the processing apparatus.

### [Overall Structure of Plasma Processing Apparatus]

At first, referring to FIG. 1, an example of the overall structure of a plasma processing apparatus 1 of an embodiment of the present invention is described. FIG. 1 illustrates an example of the structure of the plasma processing apparatus 1 of this embodiment. The plasma processing apparatus 1 is an example of a processing apparatus for processing the wafer W in the mounting stage 11 inside the processing container 10.

The plasma processing apparatus 1 includes a cylindrical processing container 10 made of aluminum having a surface that is provided with alumite treatment (an anodic oxidation process). The processing container 10 is grounded.

The mounting stage 11 is provided inside the processing container 10. The mounting stage 11 is made from, for example, aluminum (Al) and is supported by a supporting portion. With this, the mounting stage 11 is placed in a bottom portion of the processing container 10.

A gas shower head 12 in a disk-like shape is placed in the ceiling portion of the processing container 10 through a ring-like insulating member 13. The gas supply source 17 supplies a gas into the gas shower head from a gas introducing port 18. The gas passes through flow passages in multiple gas pipes 15 through a gas diffusion chamber 14 and is introduced into the processing container 10 from multiple gas vents 16.

A high frequency power source 24 is connected to the mounting stage 11 through a matching box 23. The high frequency power source 24 applies high frequency power for generating a bias voltage to the mounting stage 11. With this, the mounting stage 11 functions also as a lower electrode.

A high frequency power source 21 is connected to the gas shower head 12 through a matching box 22. The high frequency power source 21 applies high frequency power for generating plasma to the gas shower head 12. With this, the gas shower head 12 functions as an upper electrode.

The high frequency power source 21 applies high frequency power having a first frequency, for example, 60 MHz suitable for generating plasma in the processing container 10 to the gas shower head 12. The high frequency power source 24 applies a second frequency, which is for example 13.56 MHz, lower than the first frequency to the mounting stage 11.

The matching box 22 functions such that the internal impedance of the high frequency power source 21 seemingly matches the load impedance when plasma is generated inside the processing container 10. The matching box 23 functions such that the internal impedance of the high frequency power source 24 seemingly matches the load impedance when plasma is generated inside the processing container 10.

With this structure, the high frequency power from the high frequency power source 21 is capacitively applied in between the mounting stage 11 and the gas shower head 12 so that plasma is generated in a processing space U between the mounting stage 11 and the gas shower head 12. The high frequency power from the high frequency power source 21 may be applied to the mounting stage 11.

The mounting stage 11 (a lower electrode), which is arranged inside the processing container 10 and is provided to mount the wafer W on it, is an example of a first electrode. Further, the gas shower head 12 (the upper electrode) is an example of the second electrode that is arranged opposed to the first electrode. The high frequency power source 21 is an example of an electric power supply unit that applies the high frequency power to the first electrode and the second electrode.

An exhaust pipe 30 forming an exhaust port is provided at a bottom portion of the processing container 10. The exhaust pipe 30 is connected to the exhaust device 31. The exhaust device 31 is made with a vacuum pump such as a turbo molecular pump and a dry pump. The exhaust device 31 depressurizes the processing space U inside the processing container 10 to be a degree of vacuum and ejects the gas inside the processing container 10.

Multiple coils 41 to 45 are placed outside the processing container 10 on the surface (i.e., the back surface) opposite to the surface facing the mounting stage 11 and having the gas shower head 12. Among the sides of the processing container 10, the side closest to the multiple coils 41 to 45 is closest to the lower electrode as the mounting stage 11 and the upper electrode as the gas shower head 12. The multiple coils 41 to 45 are disposed apart from the gas shower head 12 around the back surface of the gas shower head 12.

One end of each coil 41 to 45 is connected to the shower head 12, and the other end of each coil 41 to 45 is connected to the ground. An adjusting mechanism 50 that controls a magnetic field strength passing through the gas shower head 12 as the upper electrode from the coils 41 to 45 is connected to the coils 41 to 45.

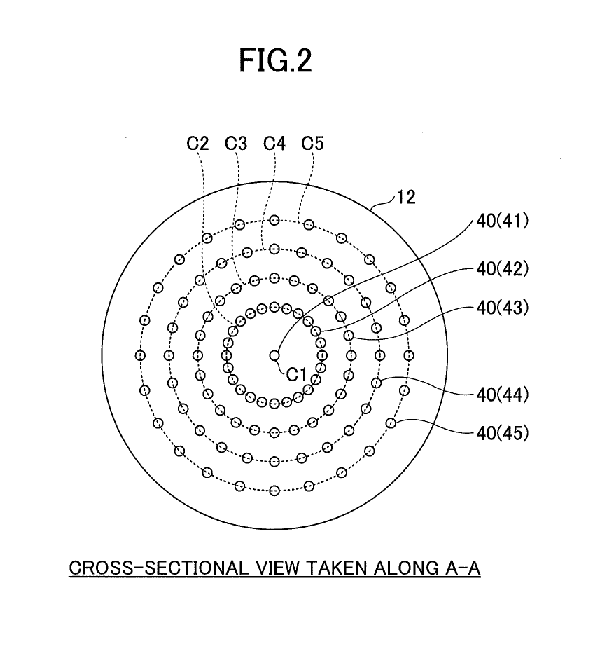

Referring to FIG. 2 as an example of the cross-sectional view taken along A-A of FIG. 1, described is an example of the coils 41 to 45 (hereinafter, collectively referred to as a “coil 40”) disposed in the vicinity of the back surface of the gas shower head 12. FIG. 2 illustrates an example of an arrangement of multiple coils of the embodiment. The coil 40 is disposed in a concentric circle shape relative to the coil 41 at the center C1 on the back surface of the gas shower head 12. Referring to FIG. 2, concentric circles C2, C3, C4, and 05 outward surround a center position C1. Along the concentric circles C2, C3, C4, and C5, multiple coils 42, 43, 44, and 45 are disposed at an even interval, respectively.

Referring back to FIG. 1, the control unit 100 includes a central processing unit (CPU) 105, a read only memory (ROM) 110, and a random access memory (RAM) 115. The CPU 105 controls an etching process or the adjusting mechanism 50 in conformity with a procedure set in a recipe stored in the ROM 110 or the RAM 115.

When a plasma process such as an etching process is performed by the above plasma processing apparatus 1, a wafer W enters from the opening of a gate valve G into the processing container while the wafer W is held on a transfer arm. The wafer W is transferred from the transfer arm to a pusher pin. When the pusher pin moves down, the wafer W is mounted on the mounting stage 11. The gate valve G is closed after the wafer W is carried in. The pressure inside the processing container 10 is depressurized to be a setup value by the exhaust device 31. The gas is introduced into the processing container 10 like shower from the gas shower head 12. The high frequency power for generating plasma is applied from the high frequency power source 21 to the gas shower head 12, and the high frequency power for generating the bias voltage is applied from the high frequency power source 24 to the mounting stage 11.

The introduced gas is ionized and dissociated by the high frequency power so as to generate plasma. The introduced gas is ionized and dissociated by the high frequency power so as to generate plasma. By the function of the plasma, a plasma process such as etching on the wafer W is performed. After completing the plasma process, the wafer W is lifted up along with rising of the pusher pin, is transferred to the transfer arm, and is carried out of the processing container.

In the above plasma processing apparatus 1, the multiple coils 40 are disposed outside the processing container 10 on the side of a surface opposite to the surface in the processing space U of the gas shower head 12. One end of each coil is connected to the electrode and the other end of each coil is connected to the ground through the adjusting mechanism 50. However, the arrangement of the multiple coils 40 is not limited thereto. The multiple coils 40 may be disposed outside the processing container 10 on the side of the surface opposite to the surface in the processing space U of the gas shower head 12. One end of each coil may be connected to the electrode through a feed line and the other end of each coil may be connected to the ground. In this case, the adjusting mechanism 50 controls magnetic field strength passing through the mounting stage 11 (the lower electrode) from the coil 40 using a return current flowing from the gas shower head 12 as the opposing electrode of the mounting stage 11 to the ground potential.

### [Adjusting Mechanism]

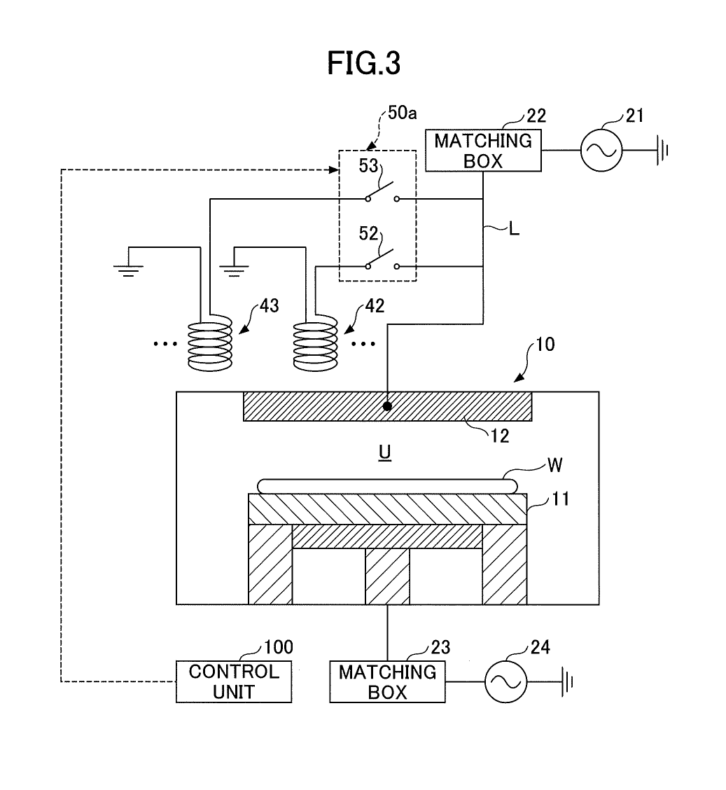

Next, referring to FIG. 3, an example of the inner structure of the adjusting mechanism 50 of the embodiment is described. FIG. 3 illustrates an example of the adjusting mechanism 50 of the embodiment. Referring to FIG. 3, the coils 42 and 43 and the adjusting mechanism 50 (the switches 52 and 53) connected to the coils 42 and 43 are illustrated but the other coils 40 and the inner structure of the adjusting mechanism 50 are omitted from illustration. Here, the other coils 40 are respectively connected to the switches on a one-to-one basis.

One end of each of the multiple coils 40 including the coils 42 and 43 is connected to one end of each of the multiple switches of the switch circuit 50a including the switches 52 and 53 on a one-to-one basis. The other end of each of the multiple switches is connected to the gas shower head 12 through the feed line L of the high frequency power source 21. The other end of each of the coils 40 is connected to the ground. The switch circuit 50a is an example of the adjusting mechanism 50. As illustrated in FIG. 3, the adjusting mechanism 50 may be provided between the multiple coils 40 and the feed line L or between the ground and the multiple coils 40.

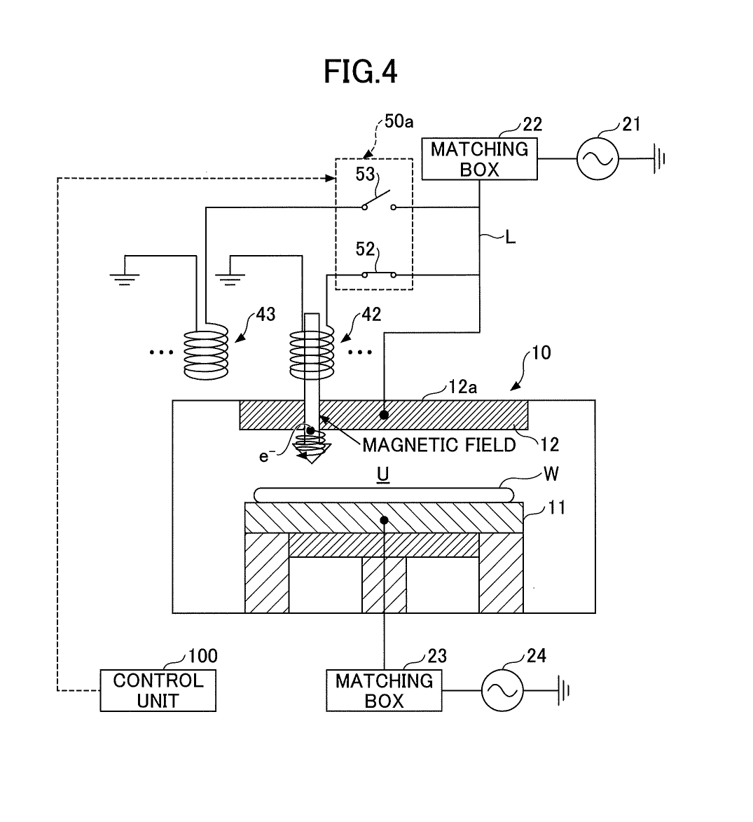

The switch circuit 50a switches over between conduction and insulation of each of multiple coils 40 in response to an instruction signal from the control unit 100. As illustrated in FIG. 4 as an example, the control unit 100 causes the switch 52 to be turned on to cause the coil 42 to be electrically conducted. The control unit 100 turns the switch 53 off to cause the coil 42 to be electrically insulated.

A part of high frequency power is supplied from the high frequency power source 21 to the electrically conducted coil 42. With this, when the high frequency current flows through the coil 42, a magnetic field is generated in a direction vertical to the back surface 12a (a ceiling portion of the processing container 10) of the gas shower head 12. The magnetic field generated by the flow of the high frequency current through the coil 42 passes through the gas shower head 12 and enters inside the processing container 10. Electrons in plasma perform a cyclone action (E×B drift) by the magnetic field entering into the processing container 10 so as to increase the plasma density of the processing space U immediately below the coil 42. With this, the etching rate in the processing space U immediately below the coil 42 can be increased.

As described above, by controlling on and off of the switch circuit 50a to control the magnetic field strength generated by the coil 40, distribution of the electric field strength inside the processing space U can be controlled in response to the distribution of multiple coils 40. With this, the plasma density in the processing space U and the distribution of the plasma density can be accurately controlled.

The multiple coils 40 are sufficient to electrically float from the electrode. For example, the multiple coils may be disposed apart from the back surface of the gas shower head 12 or may be disposed on the gas shower head 12 through the insulating member.

### [Experimental Result]

FIG. 5 illustrates an example of experimental results of electric field strength and etching rates with respect to on and off of the switch circuit of the embodiment. The etching target film of the experiment is SiO₂ film and an SiN film.

Within the embodiment, one coil is disposed at a position B in the column of E/R Circle Initialized. An end of the coil is connected to the gas shower head through the feed line of the high frequency power source, and the other end of the coil is connected to the ground through the switch circuit. the When this switch circuit is turned on, the electric field strength in the processing space U, which is immediately below the coil at the position B and its vicinity, is higher than the electric field strength in the processing space U in a state where the switch circuit is turned off. Further, in both cases where the etching target film is the SiO₂ film and the SiN film, the range of a certain etching rate when the switch circuit is turned on expands more than the range of the certain etching rate when the switch circuit is turned off.

The column E/R X-Y indicates the results of measuring the etching rate in a X direction as a radius direction of the wafer W and the etching rate in a Y direction perpendicular to the X direction as a radius direction of the wafer W. The Y direction is perpendicular to the X direction. As indicated in the column E/R X-Y, when the SiO₂ film and the SiN film are etched, the etching rates in the processing space U positioned below the coil higher when the switch circuit is turned on than when the switch circuit is turned off.

As a result, as in the column E/R X-Y, the etching rate evenness in the state where the switch circuit is turned on is lower (less preferable) than the etching rate evenness in the state where the switch circuit is turned off. From the above results, the magnetic field is generated by applying the high frequency current to the coil so as to change an electric field distribution immediately below the coil. Then, it is known that there occurs a phenomenon that the plasma density immediately below the coils is controlled by changing the electric field distribution immediately below the coils so as to partly changing the etching rate in response to arrangements of the coils.

However, in this experiment, the change of the etching rate controllable by conducting the single coil is less than 1% as a result of comparing the etching rates between the states where the switch circuit is on and off. Accordingly, it is known that the etching rate can be minutely controlled by individually control multiple coils 40.

The high frequency currents applied from the high frequency power source 21 respectively to the multiple coils 40 are controlled within a multiplying factor of one to two times. The electric field distribution under the multiple coils 40 is changed to enhance an accuracy of controlling the plasma density and improve the controllability of the etching rate.

However, the high frequency currents applied from the high frequency power source 21 respectively to the multiple coils 40 are controlled within the multiplying factor of one to two times, a high frequency current corresponding to the high frequency power of very small value being less than 1% of the high frequency power supplied to the side of the gas shower head 12 flows through the multiple coils 40. Therefore, it is known that the process is not influenced even if the part of the high frequency current is caused to be flown to the multiple coils 40.

Within the embodiment, the electric current flown through the coil is the high frequency current supplied from the high frequency power source 21. With this, a plasma density can be accurately controlled with a simple structure at a cost.

The selection ratios of the SiN film relative to the SiO₂ film are 1.7 that does not differ regardless of whether the switch circuit is on or off in the experimental results.

### Modified Example of Adjusting Mechanism

### Modified Example 1

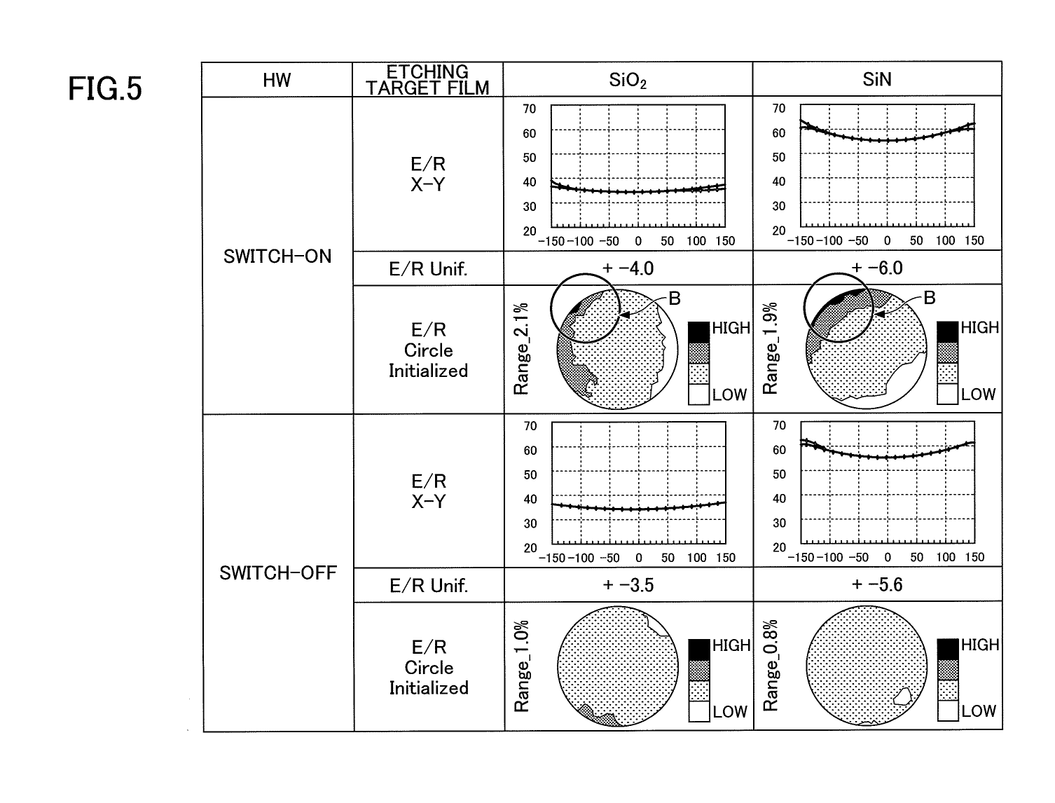

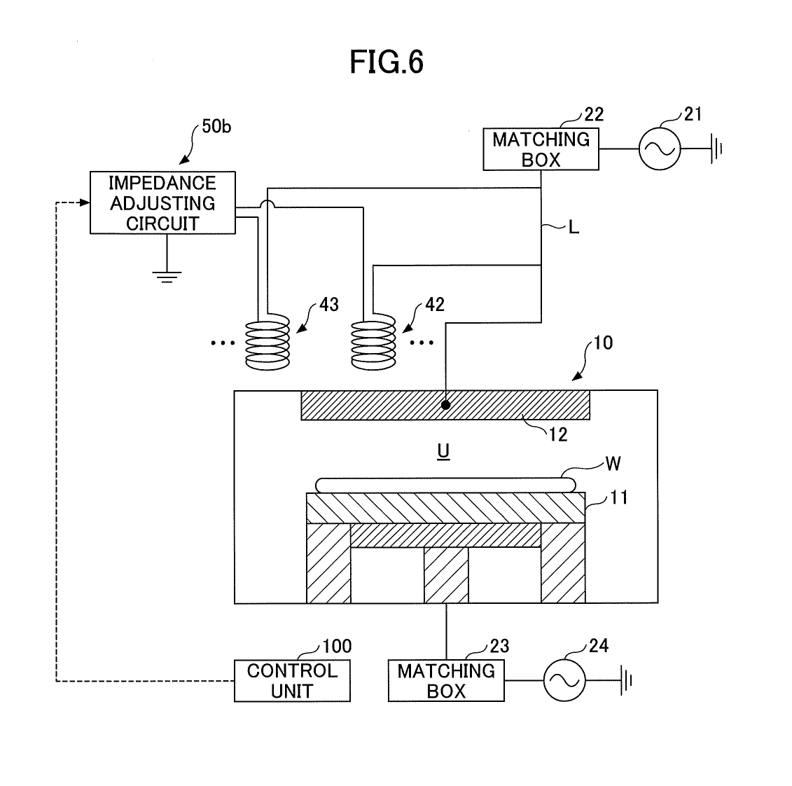

Described next is a modified example of the adjusting mechanism 50 of the embodiment and a method for controlling the plasma processing apparatus 1 using the adjusting mechanism 50 of the modified example. Referring to FIG. 6, the adjusting mechanism 50 of the modified example 1 of the embodiment is described. FIG. 6 illustrates an example of the adjusting mechanism 50 of the modified example 1 of the embodiment.

Within the modified example 1, an impedance adjusting circuit 50b is connected to all multiple coils 40. The impedance adjusting circuit 50b is an example of the adjusting mechanism 50. The impedance adjusting circuit 50b is connected to all the coils 40 so as to adjust impedances of all the coils 40. For example, the impedance adjusting circuit 50b may be formed by any one of a variable resister, a variable inductor, and a variable capacitor, or combinations of these.

The control unit 100 controls all impedances of the multiple coils 40 using the impedance adjusting circuit 50b. With this, the electric field distribution inside the processing container 10 under the multiple coils 40 is controlled so as to enhance the accuracy of controlling the plasma density and improve the controllability of the etching rate.

### Modified Example 2

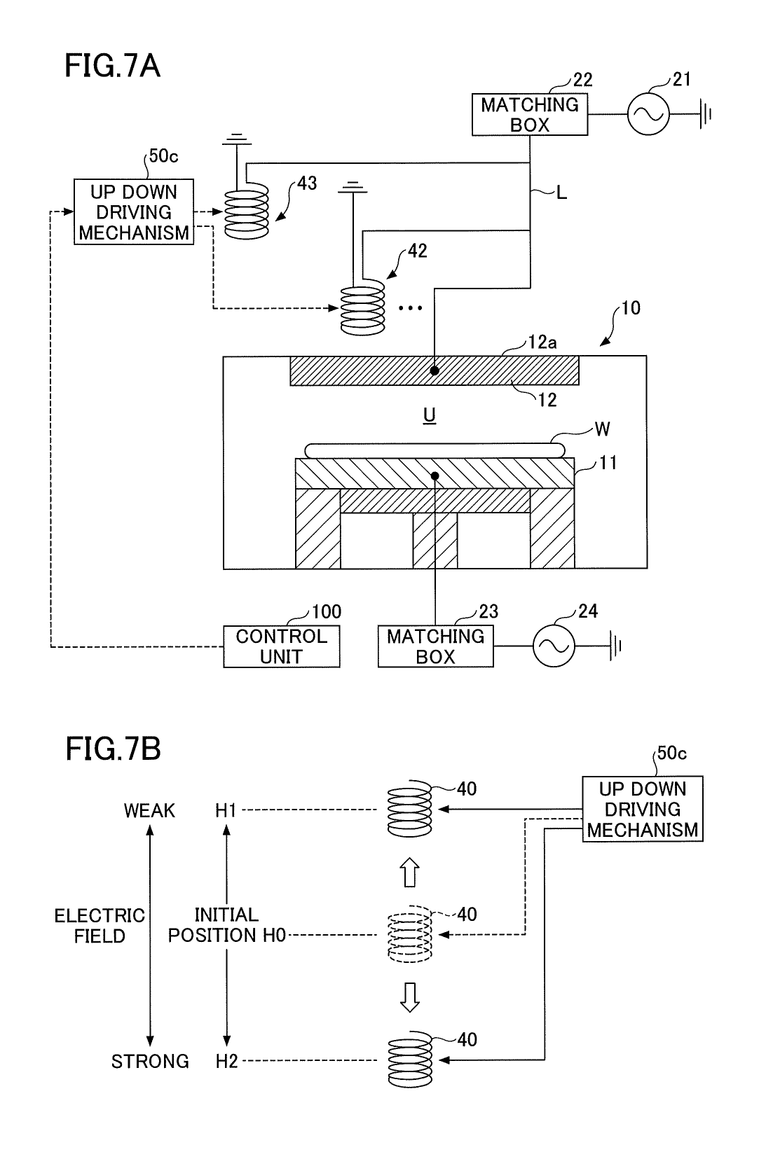

Referring to FIGS. 7A and 7B, an adjusting mechanism 50 of a modified example 2 of the embodiment is described. FIGS. 7A and 7B illustrate an example of the adjusting mechanism 50 of the modified example 2 of the embodiment. As illustrated in FIGS. 7A and 7B, the adjusting mechanism 50 of the modified example 2 includes an up down driving mechanism 50c. This up down driving mechanism 50c can make each of the multiple coils 40 move upward and downward independently in the height direction. The up down driving mechanism 50c is an example of a first driving mechanism for adjusting distances between each of the multiple coils 40 and the back surface 12a of the gas shower head 12.

The control unit 100 controls each position (each height) of the multiple coils 40 using the up down driving mechanism 50c. As illustrated in FIG. 7B, the control unit 100 uses an up down driving mechanism 50c so as to control to raise the position of the coil 40 from the initial position H0 of the coil 40 to a position H1 (H1>H0). With this, the electric field strength below the coil 40 inside the processing container 10 can be weakened.

Meanwhile, the control unit 100 uses an up down driving mechanism 50c so as to control to drop the position of the coil 40 from the initial position H0 of the coil 40 to a position H2 (H2<H0). With this, the electric field strength below the coil 40 inside the processing container 10 can be weakened. With this, an electric field distribution under the multiple coils 40 is changed so as to enhance an accuracy of controlling the plasma density and a controllability of the etching rate.

### Modified Example 3

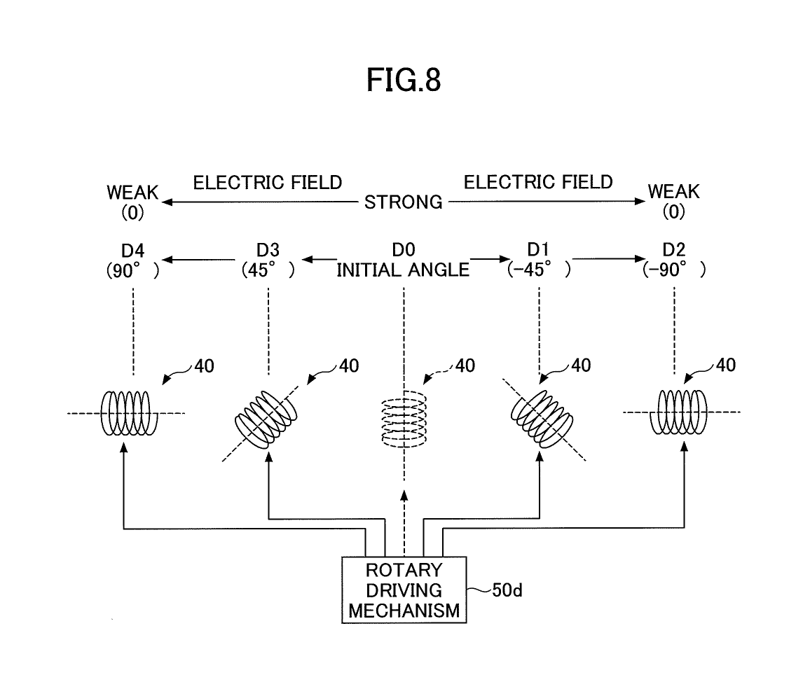

Referring to FIG. 8, an adjusting mechanism 50 of a modified example 3 of the embodiment is described. FIG. 8 illustrates an example of the adjusting mechanism 50 of the modified example 3 of the embodiment. Referring to FIG. 8, within the modified example 3, the adjusting mechanism 50 includes a rotary driving mechanism 50d. The rotary driving mechanism 50d can individually rotate each of the multiple coils 40 in the vertical direction of the back surface of the gas shower head 12. The rotary driving mechanism 50d is an example of a second driving mechanism that individually adjusts the angles of the multiple coils 40.

The control unit 100 controls each angle of the multiple coils 40 using the rotary driving mechanism 50d. Referring to FIG. 8, the control unit 100 controls the rotary driving mechanism 50d to slant each coil 40 at an angle of an angle D1 (D1=−45°) or an angle D2 (D2=−90°) from the initial angle DO. With this, the electric field strength below the coil 40 inside the processing container 10 can be weakened.

Meanwhile, the control unit 100 controls the rotary driving mechanism 50d to slant each coil 40 at an angle of an angle D1 (D3=45°) or an angle D4 (D4=90°) from the initial angle DO. With this, the electric field strength below the coil 40 inside the processing container 10 can also be weakened.

With this, the electric field distribution under the multiple coils 40 is changed so as to enhance the accuracy of controlling the plasma density and the controllability of the etching rate. When the coil 40 is slanted at the angles D2 and D4, the electric field strength below the coil 40 inside the processing container 10 can be weakened or made zero (0).

### Modified Example 4

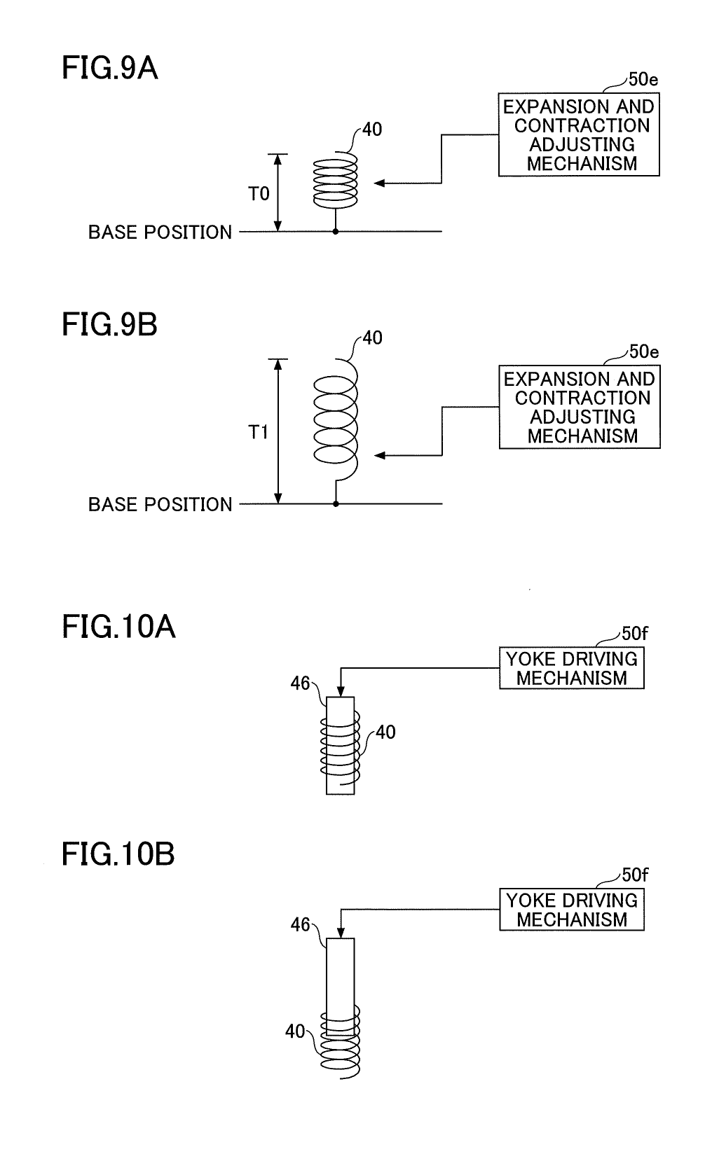

Referring to FIG. 9, an adjusting mechanism 50 of a modified example 4 of the embodiment is described. FIG. 9 illustrates an example of the adjusting mechanism 50 of the modified example 4 of the embodiment. Within the modified example 4, the adjusting mechanism 50 includes an expansion and contraction adjusting mechanism 50e. The expansion and contraction adjusting mechanism 50e can individually expand or contract each of the multiple coils 40. The expansion and contraction adjusting mechanism 50e is an example of a third driving mechanism that adjusts each length of the multiple coils 40.

The control unit 100 controls each length of of the multiple coils 40 using the contraction adjusting mechanism 50e. For example, the multiple coils 40 may be fixed to the base position. Referring to FIGS. 9A and 9B, the control unit 100 uses the contraction adjusting mechanism 50e so that the length of the coil 40 is controlled to be T1 longer than the initial length To (T1>T0). Thus, by controlling the length of the coil 40 to be longer or shorter than the initial length To, the electric field strength under the coil 40 in the processing container 10 can be changed. With this, the electric field distribution under the multiple coils 40 is changed so as to enhance the accuracy of controlling the plasma density and the controllability of the etching rate.

### Modified Example 5

Referring to FIGS. 10A and 10B, an adjusting mechanism 50 of an modified example 5 of the embodiment is described. FIGS. 10A and 10B illustrate an example of the adjusting mechanism 50 of the modified example 5 of the embodiment. Within the modified example 5, the adjusting mechanism 50 has the yoke driving mechanism 50f. Within the modified example 5, a rod-like member (hereinafter, referred to as a “yoke 46”) is provided inside each of the multiple coils 40. The yoke 46 is connected to a yoke driving mechanism 50f.

Referring to FIGS. 10A and 10B, the yoke driving mechanism 50f can move the yoke 46. The yoke driving mechanism 50f is an example of a fourth driving mechanism that adjusts insertion and extraction of the yoke 46 for each of the multiple coils 40.

The control unit 100 uses the yoke driving mechanism 501 to control movement of the yoke 46 for each of the multiple coils 50f. With this, it is possible to change magnetic field strength generated in each of the multiple coils 40. With this, it is also possible to change electric field strength generated in each of the multiple coils 40. As a result, an accuracy of controlling the plasma density can be enhanced so as to improve the controllability of the etching rate.

### Modified Example of Coil Arrangement

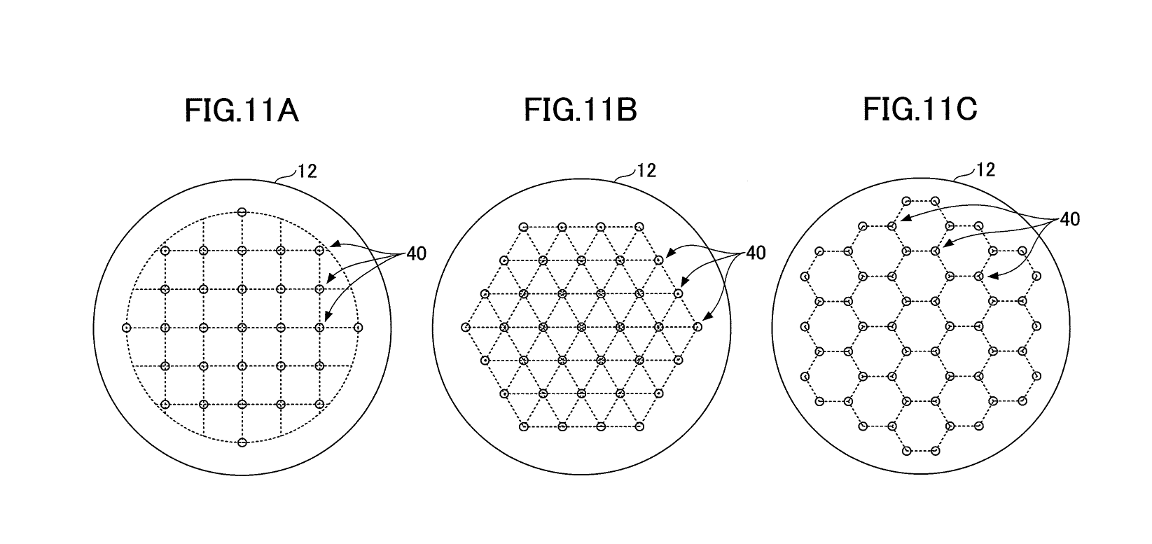

Next, referring to FIG. 11, a coil arrangement of the modified example of the embodiment is described. FIG. 11 illustrates an example of an arrangement of multiple coils of the modified example of the embodiment. The multiple coils 40 may be arranged in a shape like a concentric circle illustrated in FIG. 2, a shape like a grid illustrated in FIG. 11A, a shape like a triangle illustrated in FIG. 11B, and a shape like a honeycomb illustrated in FIG. 11C.

By making the multiple coils arrange as illustrated in FIG. 2, 11A, 11B, or 11C, it is possible to enhance an in-plane evenness of an etching rate or a controllability of an in-plane distribution of the etching rate. For example, in a case where the etching rate on the edge side of the wafer W is high, the coil 40 on the center side is controlled to enhance the etching rate on the center side so as to improve the in-plane evenness of the etching rate of the wafer W.

Within the embodiment and the modified examples, the switch circuit 50a, the impedance adjusting circuit 50b, the up down driving mechanism 50c, the rotary driving mechanism 50d, the expansion and contraction adjusting mechanism 50e, and the yoke driving mechanism 50f, which form the adjusting mechanism 50, can be simultaneously used. With this, an accuracy of controlling the plasma density can be further enhanced.

Within the embodiment and the modified examples, the number of the coils 40 may be one. In a case where the multiple coils 40 are used, the multiple coils 40 may be the same coils or different coils. Depending on the number of turns, the turning direction, and the coil length, it is possible to form the same coils or different coils.

Within the embodiment and the modified examples, a control timing for controlling the multiple coils by the control unit 100 using the adjusting mechanism 50 may be at a time of shipping the plasma processing apparatus 1, after its maintenance, of before various processes.

However, it is necessary not to provide a magnetic material in an electrode (an upper electrode or a lower electrode) on a side where the coil is disposed. This is to prevent the magnetic field that passes an electrode from the coil from being cut off by the magnetic material provided in the electrode on the side where the coil is arranged.

The plasma processing apparatus of the embodiment may be any type of Capacitively Coupled Plasma (CCP), Inductively Coupled Plasma (ICP), Radial Line Slot Antenna, Electron Cyclotron Resonance Plasma (ECR), and Helicon Wave Plasma (HWP).

For example, this processing apparatus may have the electrode in the ceiling portion of the processing container 10 or in the mounting stage 11, on which the substrate is mounted. The processing apparatus has a high frequency power source for applying high frequency power to the electrode. The processing apparatus may have the coil 40 disposed on a surface opposite to the surface to which the first electrode or the second electrode faces and on a surface on any one of the the first electrode and the second electrode, one end of the coil being connected to the any one of the the first electrode and the second electrode, another end of the coil being connected to ground.

Within the embodiment, the wafer W is described as an example of the substrate. However, the substrate is not limited to this and may be various substrates used for a Liquid Crystal Display (LCD) and a Flat Panel Display (FPD), photomask, a Compact Disk (CD) substrate, a printed wiring board, and so on.

According to an aspect of the embodiment or the like, the plasma density can be accurately controlled.

All examples and conditional language recited herein are intended for pedagogical purposes to aid the reader in understanding the invention embodiments and the concepts contributed by the inventor to furthering the art, and are to be construed as being without limitation to such specifically recited examples and conditions, nor does the organization of such examples in the specification relate to a showing of superiority or inferiority of the invention embodiments. Although the processing apparatus of the present invention have been described in detail, it should be understood that the various changes, substitutions, and alterations could be made hereto without departing from the spirit and scope of the invention.

What is claimed is:

1. A processing apparatus that processes a substrate inside a processing container, the processing apparatus comprising:
a first electrode disposed inside the processing container, the first electrode being configured to mount the substrate on it;
a second electrode disposed so as to face the first electrode;
an electric power supply unit configured to apply high frequency power to the first electrode or the second electrode;
a coil disposed on a surface opposite to the surface to which the first electrode or the second electrode faces and on a surface of any one of the first electrode and the second electrode, one end of the coil being connected to the any one of the the first electrode and the second electrode, another end of the coil being connected to ground; and
an adjusting mechanism configured to control a magnetic field strength of a magnetic field that is from the coil and passes through the coil.

2. A processing apparatus including:
a processing container, in which a substrate is processed;
an electrode that is disposed on a ceiling portion of the processing container or inside the processing container, a mounting stage for mounting the substrate functioning as the electrode;
an electric power supply unit configured to apply high frequency power to the electrode;
a coil disposed on the ceiling portion or an opposite surface of the mounting stage opposite to a processing space surface of the mounting stage on a side of a processing space, one end of the coil being connected to the electrode and another end of the coil being connected to a ground; and
an adjusting mechanism configured to control magnetic field strength of a magnetic field generated by the coil and passes through the coil.

3. The processing apparatus according to claim 1,
wherein one end of the coil is connected to the electrode through a feed line of the electric power supply unit.

4. The processing apparatus according to claim 1,
wherein the coil includes a plurality of coils, and
wherein the plurality of coils are arranged like any one of a concentric circle, a grid, a triangle, and a honeycomb.

5. The processing apparatus according to claim 4,
wherein the adjusting mechanism is provided between the electrode and the plurality of coils or between the plurality of coils and a ground.

6. The processing apparatus according to claim 4,
wherein the adjusting mechanism includes a switch circuit switching between conduction and insulation of each of the plurality of coils.

7. The processing apparatus according to claim 4,
wherein the adjusting mechanism includes an impedance adjusting circuit that adjusts an impedance of each of the plurality of coils.

8. The processing apparatus according to claim 4,
wherein the adjusting mechanism includes
a first driving mechanism configured to cause each of the plurality of coils to independently move in a height direction to adjust a distance between each of the plurality of coils and the electrode.

9. The processing apparatus according to claim 4,
wherein the adjusting mechanism includes
a second driving mechanism configured to cause a center axis of each of the plurality of coils to independently rotate on a plane vertical to the ceiling portion of the processing container so as to adjust an angle of the center axis relative to the ceiling portion for each of the plurality of coils.

10. The processing apparatus according to claim 4,
wherein the adjusting mechanism includes
a third driving mechanism configured to cause each of the plurality of coils to independently expand or contract so as to adjust a length of each of the plurality of coils.

11. The processing apparatus according to claim 4,
wherein a rod-like member made with a magnetic material is disposed inside each of the plurality of coils.

12. The processing apparatus according to claim 11,
wherein the adjusting mechanism includes
a fourth driving mechanism configured to cause the rod-like member to be inserted into and extracted from each of the plurality of coils.

13. The processing apparatus according to claim 1,
wherein the electric power supply unit applies the high frequency power to the second electrode.

14. A method for controlling a processing apparatus that processes an substrate inside a processing container including
a first electrode disposed inside the processing container, the first electrode being configured to mount the substrate on it,
a second electrode disposed so as to face the first electrode,
an electric power supply unit configured to apply high frequency power to the first electrode or the second electrode,
a coil disposed on a surface opposite to the surface to which the first electrode or the second electrode faces and on a surface of any one of the first electrode and the second electrode, one end of the coil being connected to the any one of the the first electrode and the second electrode, another end of the coil being connected to ground, and
an adjusting mechanism configured to control a magnetic field strength of a magnetic field that is from the coil and passes through the coil, the method comprising:
controlling at least one of a position, an angle, a length, and an impedance of each of the plurality of coils using the adjusting mechanism.

15. The method according to claim 14,
wherein the adjusting mechanism has a switch circuit switching between conduction and insulation of each of the plurality of coils, and
wherein the controlling the at least one of the position, the angle, the length, and the impedance of each of the plurality of coils uses the switch circuit to switch between conduction and insulation of each of the plurality of coils.

16. The method according to claim 14,
wherein the adjusting mechanism includes an impedance adjusting circuit that adjusts an impedance of each of the plurality of coils, and
wherein the controlling the at least one of the position, the angle, the length, and the impedance of each of the plurality of coils uses the impedance adjusting circuit to adjust the impedance of each of the plurality of coils.

17. The method according to claim 14,
wherein the adjusting mechanism includes a first driving mechanism configured to cause each of the plurality of coils to independently move in a height direction to adjust a distance between each of the plurality of coils and the electrode, and
wherein the controlling the at least one of the position, the angle, the length, and the impedance of each of the plurality of coils uses the first driving mechanism to control the position of each of the plurality of coils.

18. The method according to claim 14,
wherein the adjusting mechanism includes a second driving mechanism configured to cause a center axis of each of the plurality of coils to independently rotate on a plane vertical to the ceiling portion of the processing container so as to adjust an angle of the center axis relative to the ceiling portion for each of the plurality of coils, and
wherein the controlling the at least one of the position, the angle, the length, and the impedance of each of the plurality of coils uses the second driving mechanism to control the angle of each of the plurality of coils.

19. The method according to claim 14,
wherein the adjusting mechanism includes a third driving mechanism configured to cause each of the plurality of coils to independently expand or contract so as to adjust a length of each of the plurality of coils, and
wherein the controlling the at least one of the position, the angle, the length, and the impedance of each of the plurality of coils uses the third driving mechanism to control the length of each of the plurality of coils.

20. The method according to claim 14,
wherein the adjusting mechanism includes a fourth driving mechanism configured to cause the rod-like member to be inserted into and extracted from each of the plurality of coils, and
wherein the controlling the at least one of the position, the angle, the length, and the impedance of each of the plurality of coils uses the fourth driving mechanism to control the insertion and extraction of each of the plurality of coils.
